(19) United States
(12) Patent Application Publication
(10) Pub. No.: US 2026/0164854 A1
(43) Pub. Date: Jun. 11, 2026

(54) STACKED MULTI-QUANTUM WELL DIE ARCHITECTURE WITH COMMON CONTACT AND METHOD OF MANUFACTURE

(71) Applicant: LUMILEDS LLC, San Jose, CA (US)

(72) Inventors: Florent MONESTIER, Kerkrade (NL); Toni LOPEZ, Vaals (NL)

(73) Assignee: LUMILEDS LLC, San Jose, CA (US)

(21) Appl. No.: 18/972,313

(22) Filed: Dec. 6, 2024

(51) Int. Cl. H10H 20/812; H10H 20/01; H10H 29/01; H10H 29/80; H10H 29/85

(52) U.S. Cl. CPC H10H 20/812; H10H 20/017; H10H 29/0364; H10H 29/857; H10H 29/942

(57) ABSTRACT

Methods and apparatus are described herein. A lighting device includes a silicon body and a common electrical terminal. The silicon body includes first and second light emitting regions. The first light emitting region is above the second light emitting region and emits light having a different color than the first light emitting region when powered on. The common electrical terminal is electrically coupled to both the first light emitting region and the second light emitting region. The common electrical terminal has a step-shaped cross-section including a bottom surface and a first step shaped section above the bottom surface. The first step shaped section has a first horizontal contacting area and a riser portion between the bottom surface and the first horizontal contacting area. The riser portion is completely covered in a dielectric material. The horizontal contacting area and the bottom surface are at least partially exposed from the dielectric material.

### BACKGROUND

Red Indium Gallium Nitride (InGaN) quantum wells are semiconductor structures widely used in light-emitting diodes (LEDs), particularly for red light emission. Quantum wells are thin layers of semiconductor materials sandwiched between materials with a wider bandgap, creating a potential well where charge carriers (electrons and holes) can be confined in one dimension. InGaN is a ternary compound that allows for precise tuning of the energy bandgap by adjusting the ratio of indium and gallium. This makes it possible to emit light across a broad spectrum, including red, by modifying the indium concentration.

### SUMMARY

Methods and apparatus are described herein. A lighting device includes a silicon body and a common electrical terminal. The silicon body includes first and second light emitting regions. The first light emitting region is above the second light emitting region and emits light having a different color than the first light emitting region when powered on. The common electrical terminal is electrically coupled to both the first light emitting region and the second light emitting region. The common electrical terminal has a step-shaped cross-section including a bottom surface and a first step shaped section above the bottom surface. The first step shaped section has a first horizontal contacting area and a riser portion between the bottom surface and the first horizontal contacting area. The riser portion is completely covered in a dielectric material. The horizontal contacting area and the bottom surface are at least partially exposed from the dielectric material.

### BRIEF DESCRIPTION OF THE DRAWINGS

A more detailed understanding can be had from the following description, given by way of example in conjunction with the accompanying drawings wherein:

FIG. 1 is a cross-sectional view of the epitaxial architecture of a polychromatic micro-LED (μLED) die with three (3) tunnel junctions on InGaN QWs;

FIG. 2A is a cross-sectional view of an example lighting device;

FIG. 2B is a perspective view of the lighting device of FIG. 2A;

FIG. 2C is a top view of the lighting device of FIGS. 2A and 2B;

FIG. 3A is a cross-sectional view of another lighting device;

FIG. 3B is a bottom view of the lighting device of FIG. 3A;

FIG. 3C is a top view of the lighting device of FIGS. 3A and 3B;

FIG. 4A is a top view of a pixel;

FIG. 4B is a cross-section view of a multi-QW junction contact;

FIG. 5A is a top view of another pixel;

FIG. 5B is a cross-section view of another multi-QW junction contact;

FIG. 6A is a diagram of a top surface of another pixel;

FIG. 6B is a cross-sectional view of the partially conductive multi-QW contact of FIG. 6A taken along the line w-w in FIG. 6A;

FIG. 7 is a flow diagram of an example method of manufacturing a lighting device;

FIG. 8A is a cross-sectional view of a polychromatic silicon die after a first etching step;

FIG. 8B is a cross-sectional view of the polychromatic silicon die of FIG. 8A after the second etching step;

FIG. 8C is a cross-sectional view of the polychromatic silicon die of FIG. 8B after an optional third etching step;

FIG. 8D is a cross-sectional view of the polychromatic silicon die of FIG. 8C with a dielectric material provided in an opening;

FIG. 8E is a cross-sectional view of the polychromatic silicon die of FIG. 8D with portions of the dielectric material selectively removed; and

FIG. 8F is a cross-sectional view of the polychromatic silicon die of FIG. 8E with metal completely filling the opening.

### DETAILED DESCRIPTION

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Red InGaN quantum wells (QWs) make possible monolithic integration of all the primary color LEDs in a single pixel emitting the full color gamut. This could be a revolutionary development in microLED display technology, allowing for higher pixel densities (or smaller fill factors) and eliminating the need for die mass transfer from multiple wafers. Various different InGaN monolithic red, green, blue (RGB) technology concepts are theoretically possible, and none without significant challenges in fabrication and/or realizing the required performance. For example, a stack of multiple p-junctions of different emission wavelengths may be sequentially grown and independently contacted.

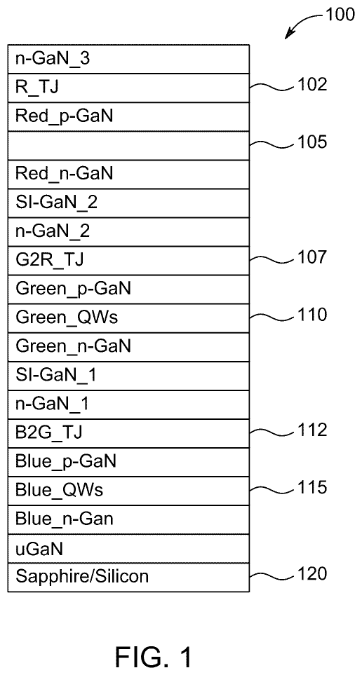

FIG. 1 is a cross-sectional view of the epitaxial architecture of a polychromatic micro-LED (μLED) die 100 with three (3) tunnel junctions on InGaN QWs. In the example illustrated in FIG. 1, the polychromic μLED die 100 is a polychromatic RGB die and includes three (3) light emitting regions. In the example illustrated in FIG. 1, the lighting regions may be or include one or more red QWs 105, one or more green QWs 110, and one or more blue QWs 115. Each of the red, green and blue QWs 105, 110 and 115 is connected by a respective tunnel junction 102, 107, and 112. The epitaxial layers are grown on a substrate 120, such as a sapphire or silicon substrate.

An RGB polychromatic die, such as the RGB polychromatic die 100, may be the most suitable polychromatic die for display applications. However, multi-QW polychromatic InGaN dies with different combinations of color can also be used for display or other types of applications. For example, a dichromatic die, such as a die with only blue and green QW junctions or cyan and amber QW junctions, may be used for any of the embodiments described herein. Additionally, the size of the pixels within a polychromatic die may vary. For example, a polychromatic die with a pixel area smaller than 20 μm may be the most suitable for direct view displays but is not necessary in some other applications, such as segmented illumination of liquid crystal on silicon displays (LCOSs) and/or digital micromirror devices (DMDs), where larger pixels may be needed to have better compromise between resolution, contrast and efficacy.

A lighting device may be formed, for example, by packaging a polychromatic die, such as the RGB polychromatic die 100 of FIG. 1, including contacting the multiple light emitting regions via electrical terminals. Different polychromatic die layouts with x by y pixels can be used. At the most basic level, six (6) electrical terminals by pixel may be provided to make the electrical connections for a 3 (three) color polychromatic die, such as the RGB polychromatic die 100 illustrated in FIG. 1 and described above. The six (6) electrical terminals may include one (1) cathode and one (1) anode for each of the three (3) QW junctions.

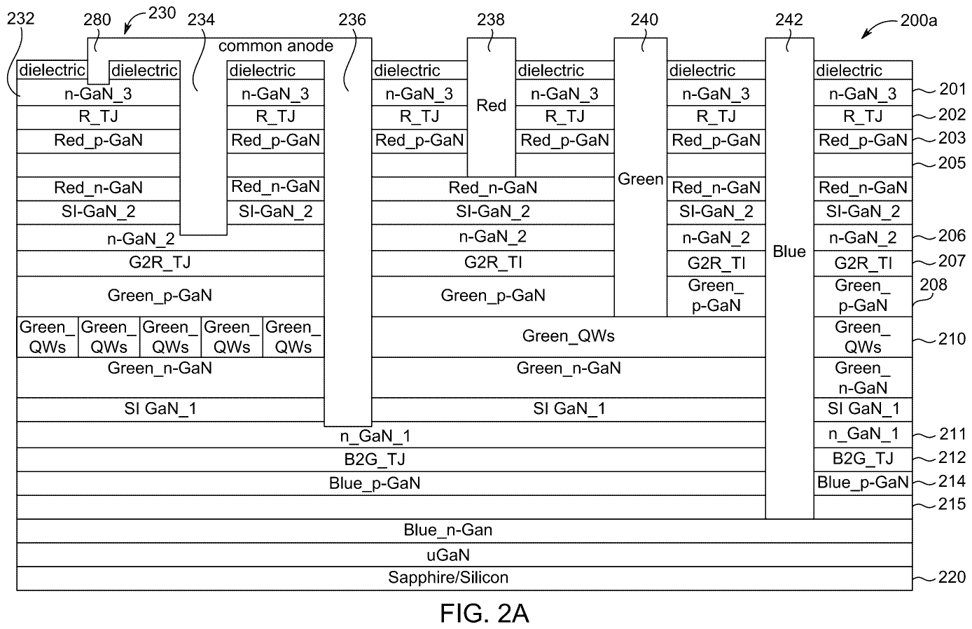

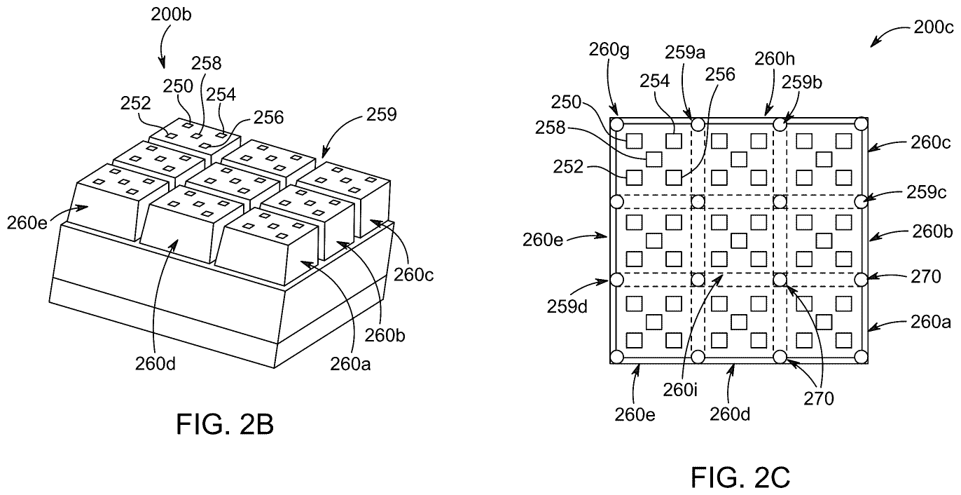

FIG. 2A is a cross-sectional view of an example lighting device 200a. In the example illustrated in FIG. 2A, the lighting device 200a is an RGB polychromatic μLED die 200a with electrical terminals. The RGB polychromatic μLED die 200a has the same epitaxial architecture as the RGB polychromatic μLED die 100 of FIG. 1, including a substrate 220, one or more red QWs 205, one or more green QWs 210 and one or more blue QWs 215. Each of the red, green and blue QWs 205, 210 and 215 is connected by a respective tunnel junction 202, 207, 212. The epitaxial layers are grown on a substrate 220, such as a sapphire or silicon substrate.

The example RGB polychromatic μLED die 200a illustrated in FIG. 2A includes four (4) separate electrical terminals by pixel. Three (3) electrical terminals are provided for cathode contact of each QW junction, and a common electrical terminal is provided for the anode. More specifically, an electrical terminal 238 contacts the red p-GaN 203, an electrical terminal 240 contacts the green p-GaN 208, and an electrical terminal 242 contacts the blue p-GaN 214. Each of the electrical terminals 238, 240 and 242 is provided in its own via (not labeled). A common anode electrical terminal 230 contacts the n-GaN 232, the n-GaN 206 and the n-GaN 211, providing a common anode electrical terminal for the red, green and blue QWs 205, 210 and 215. While a single common anode electrical terminal, the common anode electrical terminal 230 is provided in three (3) separate vias 280, 234 and 236 to provide the anode electrical contact for each of the three (3) QWs.

FIG. 2B is a perspective view of the lighting device of FIG. 2A. In the example illustrated in FIG. 2B, the lighting device 200b is a 3×3 RGB polychromatic die 200 b including nine (9) pixels. In the example illustrated in FIG. 2B, only pixels 260a, 260b, 620c, 260d, and 260e are labeled, and the 3×3 RGB polychromatic die 200b is shown without the contacts. Without the contacts provided, it can be seen that each pixel in the 3×3 RGB polychromatic die 200b includes five (5) vias 250, 252, 254, 256 and 258. In the example illustrated in FIG. 2B, the five (5) vias correspond to the vias 232, 234 and 236 for the common anode electrical terminal 230 (shown in FIG. 2A) and the red and green cathode electrical terminals 238 and 240 (also shown in FIG. 2A). The blue anode electrical terminal 242 may be provided in the streets between adjacent pixels in the array. One such street 259 is labeled in FIG. 2B, although the blue anode electrical terminal 242 can be provided in any or all streets in the die, as well as partially within the street or streets, as will be explained in more detail below.

FIG. 2C is a top view of the lighting device of FIGS. 2A and 2B. The 3×3 RGB polychromatic die 200c of FIG. 2C includes nine (9) pixels 260a, 260b, 260c, 260d, 260e, 260f, 260g, 260h, and 260i. Streets 259a, 259b, 259c, and 259d are provided between adjacent pixels. As can be seen in FIG. 2C, five (5) vias 250, 252, 254, 256, and 258 pass through the pixel area of each pixel 260a, 260b, 260c, 260d, 260e, 260f, 260g, 260h, and 260i to provide the common anode electrical terminal and red and green cathode electrical terminals for each pixel. Blue cathode electrical terminals 270 (only 3 are labeled in FIG. 2C) are provided in the streets 259a, 259b, 259c, and 259d.

While the embodiment illustrated in FIGS. 2A, 2B and 2C provides for a common anode electrical terminal and individual cathode electrical terminals for each of the one or more red, one or more green, and one or more blue QWs for each pixel, one of ordinary skill in the art will understand that the reverse arrangement is also applicable to the embodiments described herein such that a common cathode and individual anode electrical terminals for each of the one or more red, one or more green, and one or more blue QWs per pixel may be used.

In the lighting device 200 illustrated in FIGS. 2A, 2B and 2C, to form the streets between pixels, the epitaxial stack is etched nearly through the entirety of the epitaxial stack, which reduces light leakage and increases the contrast between neighboring pixels. However, five (5) different vias by pixel must still be etched within the pixel area, which therefore requires more etched areas within the pixel space, considerably limiting the area where current is generated and increasing optical extraction losses. Optical losses in the n vias region can be high because, for example, overlap of n-via edges with insulating material will be needed to avoid short circuit and current leakages.

Furthermore, for larger pixel size (e.g., in the range of 40 to 300μm), the n contact area of each QW junction will have to be scaled with the pixel area to avoid high forward voltage (Vf) and current crowding. This can be done by increasing the number of n vias or by increasing the diameter of the n vias of the green and red QW junctions, or, ideally, by having the n contact area of each QW junction along the edge of each pixel. Providing the n contact on the street area between pixels will also help to avoid light leakage between pixels and increase contrast. For such larger RGB polychromatic pixels, it may be desirable to increase the cathode contact area of each QW junction. One way to do this is to provide the cathode contact along the pixel edge. It may also be desirable to avoid placing n-contacts within the pixel area so as to not reduce the active area where current is generated and to not reduce optical extraction efficacy.

Embodiments described herein provide for a polychromatic die architecture that may increase the n-GaN cathode contact area without reducing the active area. In such embodiments, a common n contact for each QW junction may be provided only on the pixel edge to avoid active area reduction and reduce optical extraction losses. This common n contact area may be provided using several partial epitaxial layer etching and dielectric layer patterning steps, resulting in a common multi-QW, step-shaped, n contact. In embodiments described herein, this common, step-shaped contact area may be formed in the streets between pixels and may have a step-shaped profile providing space for the electrical contact to the n-GaN of each QW junction. Such contact (or electrical terminal) will be referred to hereafter as a multi-QW contact for ease of reference.

A multi-QW contact may provide a larger n contact area without dramatic reduction of the active area and with limited reduction of extraction efficiency, which may be particularly beneficial for large pixel sizes in the range of 40 to 300 μm, for example, where a large n-contact area is needed. Of course the multi-QW contact area will be larger than a single QW n-contact area, but this penalty will be limited when used in such a large pixel where a few μm increase of the street width represents a very small portion of the pixel area.

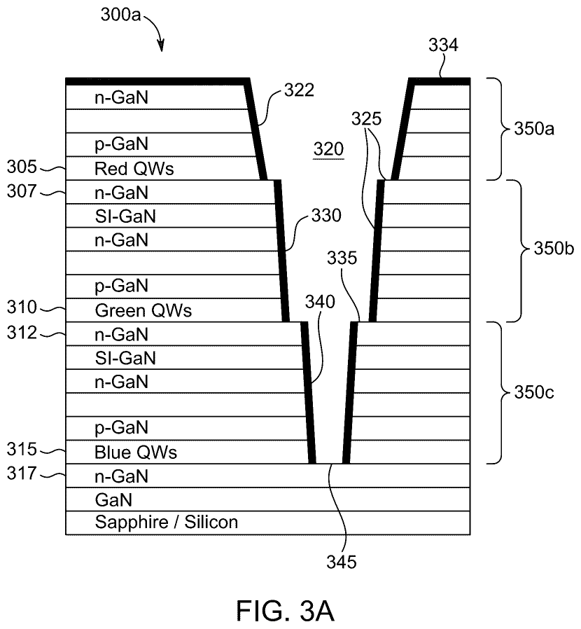

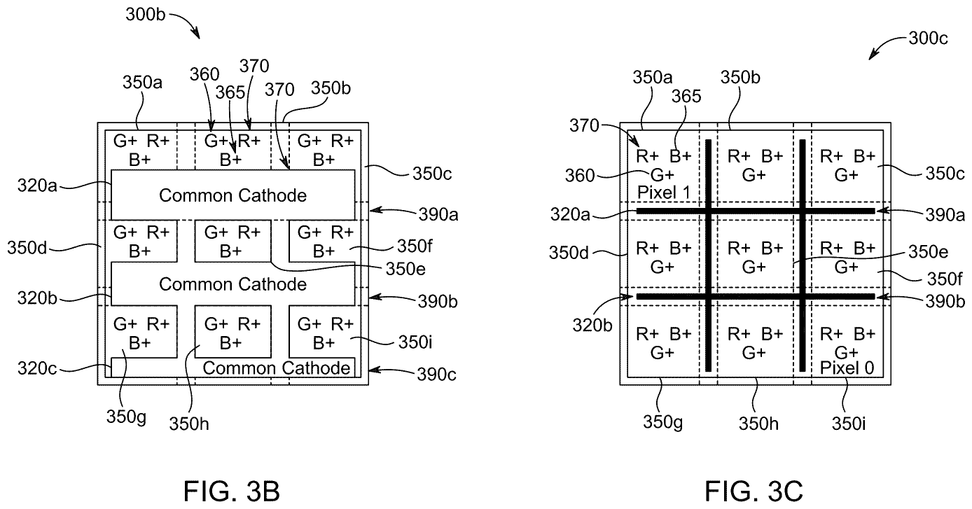

FIG. 3A is a cross-sectional view of another lighting device 300a. In the example illustrated in FIG. 3A, the lighting device 300a is an RGB polychromatic die 300a with a multi-QW contact 320. The RGB polychromatic die 300a is similar to the RGB polychromatic die 200a of FIG. 2A, including one or more red QWs 305, one or more green QWs 310 and one or more blue QWs 315. The multi-QW contact 320 includes one (1) step-shaped area for each of the QWs. The multi-QW contact 320 includes a first step-shaped area 350a for contacting the red n-GaN layer 307, a second step-shaped area 350b for contacting the green n-GaN layer 312, and a third step-shaped area 350c for contacting the blue n-GaN layer 317.

In the example illustrated in FIG. 3A, the multi-QW contact area is formed from three (3) etching areas, each having a different diameter, separated by horizontal parts 325, 335, and 345 that are not covered by dielectric 334 and therefore allow electrical contact between metal and the n-GaN layer of each QW junction. Riser portions 322, 330 and 340 connect the horizontal parts 325, 335 and 345 and may be entirely vertical or sloped and are coated (or covered) by a dielectric material 334. More specifically, the step shaped area 350a includes an etching area that is lined with the dielectric material 334 and a horizontal contacting area 325 that is exposed from the dielectric material 334. The step shaped area 350b includes an etching area that is lined with the dielectric material 334 and a horizontal contacting area 335 that is exposed from the dielectric material 334. The step shaped area 350c includes an etching area that is lined with the dielectric material 334 and a horizontal contacting area 345 (also the lower-most or bottom surface of the multi-QW contact 320) that is exposed from the dielectric material 334. The deepest contact area is the one contacting the n-GaN of the Blue QW junction.

Each of the three (3) etching areas in the example multi-QW contact 320 illustrated in FIG. 3A may be fully or partially filled (or lined) with a metal material to make an electrical pathway between the multi-QW contact 320 and the n-GaN layers 307, 312 and 317 for each of the red, green and blue QWs 305, 310 and 315.

FIG. 3B is a bottom view of the lighting device of FIG. 3A. In the example illustrated in FIG. 3B, the lighting device 300b is a 3×3 RGB polychromatic die 300b, such as the 3×3 RGB polychromatic die 300a of FIG. 3A. In the example illustrated in FIG. 3B, the 3×3 RGB polychromatic die 300a includes nine (9) pixels 350a, 350b, 350c, 350d, 350e, 350f, 350g, 350h, and 350i. As mentioned above with respect to FIG. 3A, the multi-QW contact 320 includes three (3) etching areas with the largest diameter etching area being provided for the red QW 305 and the smallest diameter etching area being provided for the blue QW 315.

In the example illustrated in FIG. 3B, one multi-QW contact 320 may be provided for each row (or column) of pixels, with the multi-QW contact 320 being provided in a street adjacent the row of pixels it is contacting. In the example illustrated in FIG. 3B, a multi-QW contact 320a is provided in street 390a, a multi-QW contact 320b is provided in street 390b, and a multi-QW contact 320c is provided in street 390c. Orienting the multi-QW contacts 320a, 320b, and 320c in this way enables the widest portion of the contact to be provided on the bottom surface of the 3×3 RGB polychromatic die 300b where it is not blocking light-emission from the light-emitting (or top) surface of the LED die while maximizing the contact area.

Three (3) individual contact terminals may also be provided within the pixel area of each pixel 350a, 350b, 350c, 350d, 350e, 350f, 350g, 350h, and 350i. More specifically, an anode electrical terminal 370 contacting the p-GaN layer for the red QW 305, an anode electrical terminal 365 contacting the p-GaN layer for the green QW 310, and an anode electrical terminal 370 contacting the p-GaN layer for the blue QW 315 are shown.

FIG. 3C is a top view of the lighting device of FIGS. 3A and 3B. As can be seen, in the lighting device 300c, only the anode contact terminals 360, 365 and 370 are provided within the pixel area of each of the pixels 350a, 350b, 350c, 350d, 350e, 350f, 350g, 350h, and 350i in the array. Because the multi-QW contacts 320a and 320b decrease in diameter from the bottom surface towards the top, light-emitting surface of the die, they may not extend into the pixel area of any of the pixels 350a, 350b, 350c, 350d, 350e, 350f, 350g, 350h, and 350i, maximizing the portion of the pixel area available for light emission.

The example multi-QW contact illustrated in FIG. 3A includes three (3) step-shaped n contact regions 350a, 350b, and 350c, where 3 (three) doped GaN layers of each QW junction are electrically connected in common. However, the embodiments described herein may be used for a lighting device having more or less than three (3) color QWs by increasing or decreasing the step-shaped n contact regions in the multi-QW contact. The multi-QW contact may be formed on the street area between pixels (as illustrated in FIG. 3A). One of ordinary skill in the art will recognize that the multi-QW contact may be a common cathode or anode, although a common cathode is shown in FIGS. 3A, 3B and 3C.

Multi-QW contacts, such as the multi-QW contact 320 illustrated in FIG. 3A, may be patterned as a trench (contour) on the edges of non-etched areas. However, step-shaped vias or slots within the active region can be also patterned. A combination of both types of patterns may also be used.

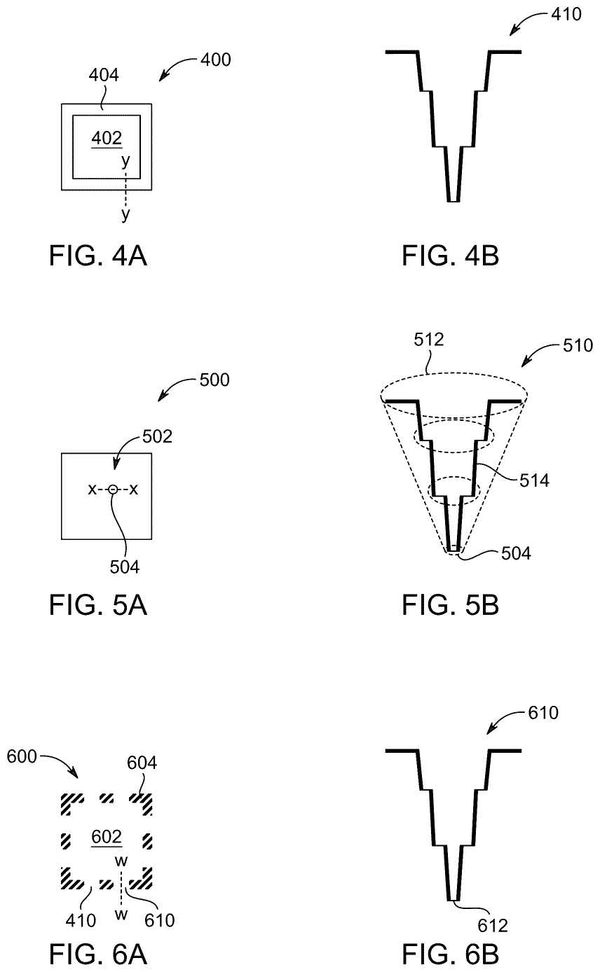

FIG. 4A is a top view of a pixel 400, such as any of the pixels described herein. The pixel 400 has a pixel area 402 (for example, a top surface of which may be the light-emitting top surface of a pixel in any the lighting devices described herein). A trench area (for example, corresponding to the streets of any of the lighting devices described herein) surrounds the pixel area 402. FIG. 4B is a cross-section view of a multi-QW contact 410. The cross section is taken along the line y-y in FIG. 4A. In this example, the multi-QW contact 410 is provided primarily in the trench 404 (with the wider lower portions of the multi-QW contact 410 potentially extending outside of the boundaries of the trench 404 underneath the light-emitting, top surface of the pixel 400.

FIG. 5A is a top view of another pixel 500, such as any of the pixels described herein. In FIG. 5A, only the pixel area 502 is shown. A top surface of the pixel 500 may be the light-emitting top surface of a pixel in any of the lighting devices described herein. In the example illustrated in FIG. 5A, a multi-QW contact is located within the pixel area 502 of the pixel 500, as represented by the contact portion 504 in FIG. 5A. FIG. 5B is a cross-section view of a multi-QW junction contact 510. The cross section is taken along the line x-x in FIG. 5A. In the example illustrated in FIG. 5B, the multi-QW contact 510 has a more rounded or conical shape 512, with the bottom surface of the multi-QW contact 510 corresponding to the contact portion 504 in FIG. 5A. As can be seen, to the extent a multi-QW contact, such as the multi-QW contact 510, is provided within the pixel area 502, only a small portion of the multi-QW junction contact takes up space within the pixel area 502, while the wider portions of the multi-QW junction contact are disposed only under the top, light-emitting surface of the pixel area 502.

In embodiments, such as illustrated in FIG. 4A, where the multi-QW contact is formed primarily in the trench area, the multi-QW contact may extend the entire length of the trench. However, it may be desirable to provide a number, n, of thinner, step-shaped multi QW junction contacts at some locations, such as to obtain a specific current distribution. In such embodiments, the bottom surface of the multi-QW contact situated on the bottom of the blue n-GaN layer of the polychromatic μLED die may be covered, at least partially, by a dielectric material.

FIG. 6A is a diagram of a top surface of another pixel 600. Similar to the embodiment illustrated in FIG. 4A, the pixel 600 has a trench 604 surrounding a pixel area 602. Multi-QW contacts are provided primarily in the trench 604 (in a manner similar to that described above with respect to FIG. 4A). In FIG. 6A, only two of the n multi-QW contacts are labeled. A first multi-QW contact 410 is the same as the multi-QW contact 410 of FIG. 4B and will not be described further here. A multi-QW contact 610 is a partially conductive multi-QW contact 610.

FIG. 6B is a cross-sectional view of the partially conductive multi-QW contact 610 of FIG. 6A taken along the line w-w in FIG. 6A. As can be seen from FIG. 6B, and in comparison with the multi-QW contact 410 of FIG. 4B, the bottom surface of the partially conductive multi-QW contact 610 is completely covered with the dielectric 612. While the entire bottom surface of the partially conductive multi-QW contact 610 is covered by the dielectric 612 in FIG. 6B, depending on the desired current distribution, only part of the bottom surface of the multi-QW contact 610 may be covered by the dielectric 612. Additionally or alternatively, the contact portion to the n-GaN or p-GaN for one, more than one, or all of the QW junctions in the polychromatic μLED may have a partial electrical contact (i.e., not just the contact portion to the n-GaN or P-GaN for the blue QW junction). The partial electrical contact layout (e.g., position or dielectric openings) may be different for each QW junction (for example based on the dielectric opening positions). This may enable a lighting device that has a different spatial emission profile for each (or at least one) of the multiple QW junctions for each of the pixels.

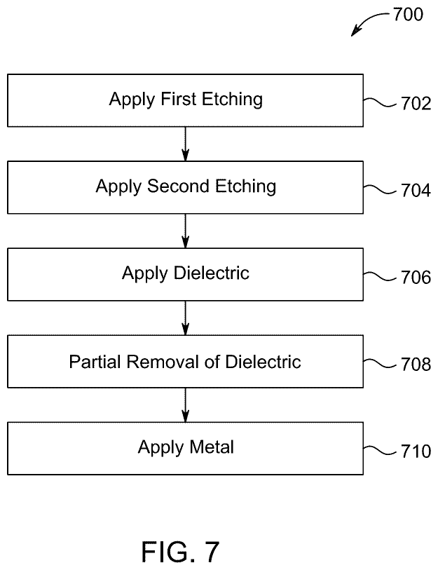

FIG. 7 is a flow diagram 700 of an example method of manufacturing a lighting device. A silicon body may first be manufactured or otherwise obtained. The silicon body has at least two light-emitting areas, at least a first light-emitting area and a second light-emitting area that are vertically stacked with one above the other, such as any of the polychromatic silicon dies described above. Each of the light-emitting regions may be configured to emit light having a different color when powered on. The term color, as used for this purpose, may be considered to correspond to a particular wavelength range of energy emission. For example, a red color light emission may correspond to energy in the range of 240-360 nm, a green color light emission may correspond to energy in the range of 520-530 nm, and a blue color light emission may correspond to energy in the range of 450-475 nm, although the exact ranges may vary. The term color may also be considered to apply to energy that is not visible, such as ultraviolet (UV), which may correspond to energy in the range of 240-360 nm, or infrared (IR), which may correspond to energy in the range of 660-900 nm, although the exact ranges may vary.

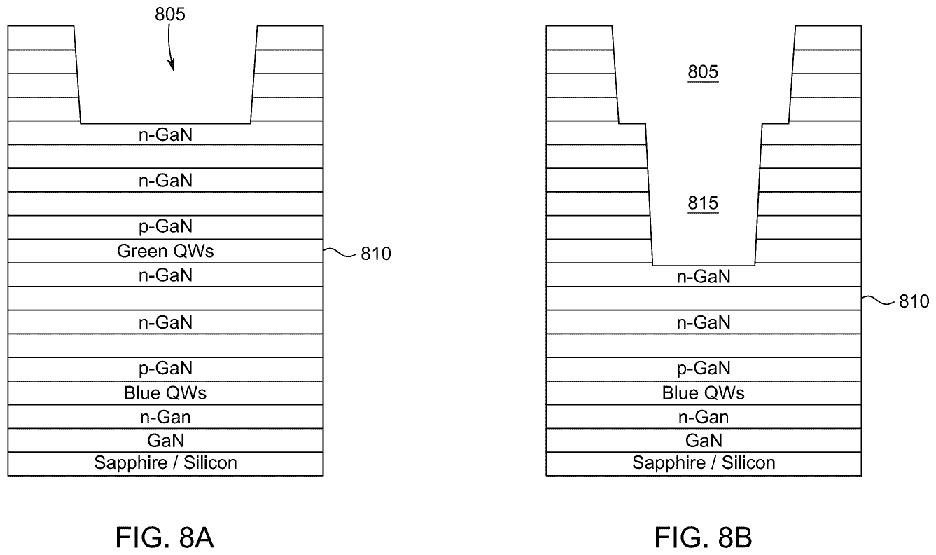

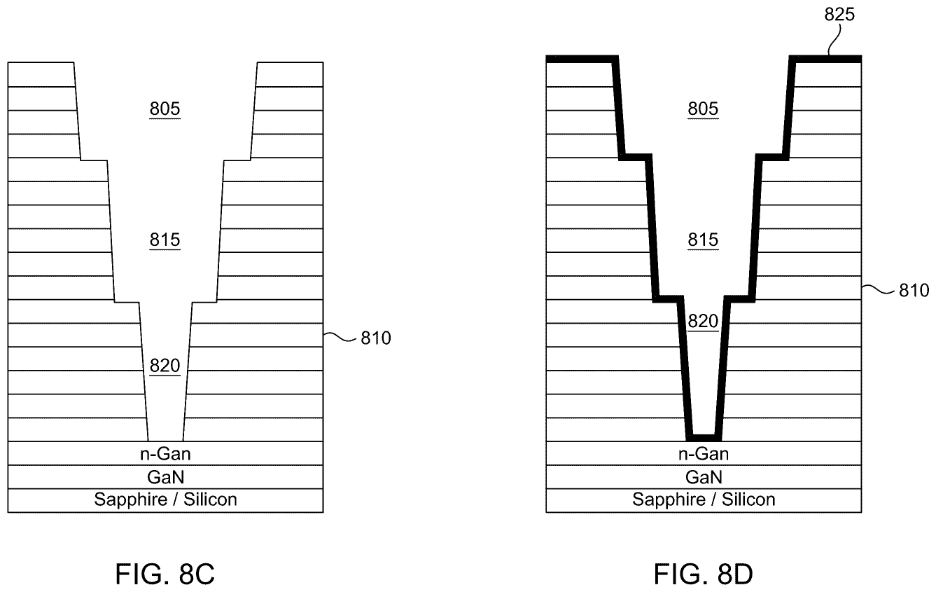

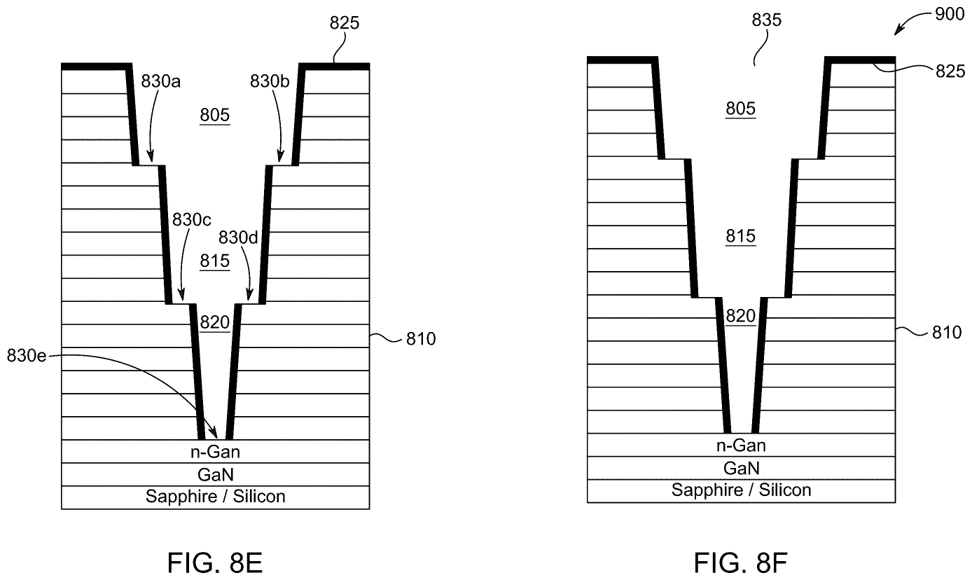

The die may be etched in a first etching step (702), for example to create a first etching area. FIG. 8A is a cross-sectional view of a polychromatic silicon die 810 after the first etching step. As shown in FIG. 8A, the first etching area 805 may be a relatively large region (relative to the additional etching areas formed later in the process). The first etching step may be performed by etching the polychromatic silicon die 810 to a limited depth. Subsequent etching steps may then be performed to create the addition etching areas.

Returning to FIG. 7, the die may be etched in a second etching step (704) to create a second etching area. FIG. 8B is a cross-sectional view of the polychromatic silicon die 810 after the second etching step. As shown in FIG. 8B, the second etching area 815 may be a narrower region (relative to the first etching area 805). The second etching step may be performed by further etching the polychromatic silicon die 810 to a limited depth.

While not illustrated in FIG. 7, additional etching steps may optionally be included in the method to create additional etching areas, such as for an RGB or other die that may have three (3) or more light-emitting regions. By way of example, FIG. 8C is a cross-sectional view of the polychromatic silicon die 810 after an optional third etching step. As shown in FIG. 8C, the third etching area 820 may be even narrower than the second etching area 815. Additionally, narrower etching areas may be created for a polychromatic die having more than three (3) light-emitting regions.

Returning to FIG. 7, a dielectric material may be provided (706) in the opening in the polychromatic silicon die corresponding to the first, second (and optionally third) etching regions 805, 810, and 815. FIG. 8D is a cross-sectional view of the polychromatic silicon die 810 with the dielectric material 825 provided in the opening. The dielectric material can, as shown, be coated or otherwise provided in the opening after all of the etching areas have been formed. Alternatively, the dielectric material can be applied after each of the first, second (and optionally third) etching steps such as by coating each etching area with a thin layer of the dielectric material.

Returning to FIG. 7, the dielectric material deposited in 706 is selectively removed. FIG. 8E is a cross-sectional view of the polychromatic silicon die 810 with portions of the dielectric material 825 selectively removed. As shown in FIG. 8E, the dielectric material 825 is selectively removed from the horizontal contacting portions 830a, 830b, 830c, 830d and 830e. However, as described above, such as with respect to FIG. 6B, for example, some of the dielectric material 825 can be left on portions of one, some, or all of the horizontal contacting portions 830a, 830b, 830c, 830d and 830e as desired to control current distribution, for example.

As mentioned above, the dielectric material 825 may be deposited in a single step or in multiple steps (depositing the dielectric material, for example, after each etching step). Similarly, selective removal of the dielectric material 825 may be performed in a single step, after all of the etching steps are completed, or after each etching step. Removal of the dielectric may be done, for example, by etching or laser ablation.

Returning to FIG. 7, a multi-QW contact may be formed in the opening corresponding to etching areas 805, 815 and 820 by filling, either partially or fully, or otherwise applying a metal material into the opening. FIG. 8E is a cross-sectional view of the polychromatic silicon die 810 with metal 835 completely filling the opening. Thereby, a lighting device 900, including a polychromatic silicon die and multi-QW contact, is formed. While not illustrated in FIG. 7, individual contacts (e.g., the anode contacts) may be formed, for example, within the pixel area, as described above.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

What is claimed is:

1. A lighting device comprising:
a silicon body comprising a first light emitting region and a second light emitting region, wherein the first light emitting region is above the second light emitting region and is configured to emit light having a different color than the first light emitting region when powered on; and
a common electrical terminal electrically coupled to both the first light emitting region and the second light emitting region,
wherein the common electrical terminal has a step-shaped cross-section comprising a bottom surface and a first step shaped section above the bottom surface, wherein the first step shaped section comprises a first horizontal contacting area and a riser portion between the bottom surface and the first horizontal contacting area, wherein the riser portion is completely covered in a dielectric material, and the horizontal contacting area and the bottom surface are at least partially exposed from the dielectric material.

2. The lighting device of claim 1, wherein the common electrical terminal is one of an anode electrical terminal or a cathode electrical terminal.

3. The lighting device of claim 1, wherein the silicon body comprises an array of a plurality of pixels, wherein each of the plurality of pixels comprises a pixel area comprising a portion of the silicon body including a portion of each of the first and second lighting regions, and wherein each of the plurality of pixels is separated from any neighboring pixel by at least one of a plurality of streets.

4. The lighting device of claim 3, wherein the common electrical terminal is disposed primarily in at least one of the plurality of streets.

5. The lighting device of claim 3, wherein each pixel further comprises one additional electrical terminal per light-emitting region within the pixel area.

6. The lighting device of claim 5, wherein the first light emitting region comprises a first quantum well (QW) with a corresponding first n-type region and a corresponding first p-type region, and the second light emitting region comprises a second QW with a corresponding second n-type region and a corresponding second p-type region.

7. The lighting device of claim 6, wherein the bottom surface of the common electrical terminal is electrically coupled to one of the second n-type region or the second p-type region of the second QW, and the first horizontal contacting area is electrically coupled to one of the first n-type region of the first p-type region of the first QW.

8. The lighting device of claim 4, wherein a plurality of the common electrical terminals are disposed primarily in at least one of the streets.

9. The lighting device of claim 1, wherein only a portion of at least one of the horizontal contacting areas is fully exposed from the dielectric material.

10. A method of manufacturing a lighting device, the method comprising:
obtaining a polychromatic silicon die comprising a first light emitting region and a second light emitting region, wherein the first light emitting region is above the second light emitting region and is configured to emit light having a different color than the first light emitting region when powered on;
etching the polychromatic silicon die to the first light emitting region to form a first step shaped section, wherein the first step shaped section has a first horizontal contacting area and a first riser portion;
after etching the polychromatic silicon die to the first light emitting region, further etching the polychromatic silicon die to the second light emitting region to form a second step shaped section below the first step shaped section, wherein the second step shaped section has a bottom surface contacting area and a second riser portion;
lining the first and second step shaped sections with a dielectric material;
partially removing the dielectric material at the bottom surface contacting area and the first horizontal contacting area; and
after lining the first and second step shaped sections with the dielectric material, at least partially filling the first and second step shaped sections with a metal material to form a common electrical terminal.

11. The method of claim 10, wherein the common electrical terminal is one of an anode electrical terminal or a cathode electrical terminal.

12. The method of claim 11, wherein the polychromatic silicon die comprises an array of a plurality of pixels, wherein each of the plurality of pixels comprises a pixel area comprising a portion of the polychromatic silicon die including a portion of each of the first and second lighting regions, and wherein each of the plurality of pixels is separated from any neighboring pixel by at least one of a plurality of streets.

13. The method of claim 12, wherein the etching and the further etching are performed primarily in at least one of the plurality of streets.

14. The method of claim 12, wherein the first light emitting region comprises a first quantum well (QW) with a corresponding first n-type region and a corresponding first p-type region, and the second light emitting region comprises a second QW with a corresponding second n-type region and a corresponding second p-type region.

15. The method of claim 14, wherein:
the etching the polychromatic silicon die to the first light emitting region further comprises etching the polychromatic silicon die to one of the n-type region or the p-type region of the first light emitting region, and
the further etching the polychromatic silicon die to the second light emitting region comprises etching the polychromatic silicon die to one of the n-type region or the p-type region of the second light emitting region.

16. The method of claim 15, further comprising
etching a plurality of vias within the pixel area of each of the plurality of pixels, wherein the plurality of vias comprise at least a first via etched to an opposite one of the n-type region or the p-type region of the first lighting region; and
at least partially filling the plurality of vias with a metal material to form a plurality of individual n-type or p-type electrical terminals within the pixel area of each of the plurality of pixels.

17. The method of claim 12, wherein the partially removing the dielectric material at the bottom surface contacting area and the first horizontal contacting area comprises leaving in place at least one of a portion of the dielectric material at the bottom surface contacting area or a portion of the dielectric material at the first horizontal contacting area.

18. The method of claim 17, further comprising determining an amount of the dielectric material to partially remove from the bottom surface contacting area and the first horizontal contacting area based on a desired current distribution within each of the plurality of pixels.

19. The method of claim 10, further comprising repeating the etching and further etching to form at least one additional common electrical terminal in a street adjacent each pixel such that each pixel is contacted by at least two common electrical terminals.

20. The method of claim 10, wherein the second step-shaped region has a wider cross-section than the first step-shaped section.
